(19) United States
(12) Patent Application Publication
(10) Pub. No.: US 2026/0312585 A1
(43) Pub. Date: Oct. 8, 2026

(54) SWITCH DEVICE

(71) Applicant: KABUSHIKI KAISHA TOKAI RIKA DENKI SEISAKUSHO, Aichi (JP)

(72) Inventors: Takao IMAI, Aichi (JP); Yosuke NAITO, Aichi (JP); Takuya GOTO, Aichi (JP); Masayoshi AMANO, Aichi (JP)

(73) Assignee: KABUSHIKI KAISHA TOKAI RIKA DENKI SEISAKUSHO, Aichi (JP)

(21) Appl. No.: 19/577,562

(22) Filed: Mar. 25, 2026

(30) Foreign Application Priority Data
Apr. 8, 2025 (JP) 2025-063728

(51) Int. Cl. H03K 17/96

(52) U.S. Cl. CPC H03K 17/9622; H03K 2217/96015

(57) ABSTRACT

A switch device includes a panel including an operation area where an operation is performed by a user, a housing to which the panel is fixed, and a sensor sheet that includes an electrically insulating base material and a detection conductive portion and is fixed to the housing, the detection conductive portion being provided on the base material and detecting proximity or contact of a finger of the user to or with the operation area. The sensor sheet includes an electrode sheet portion on which an electrode portion is formed, and a wiring sheet portion on which a wiring portion is formed and which is bent from the electrode sheet portion. The housing includes a raised portion protruding toward a blank portion of the wiring sheet portion where the wiring portion does not exist. The wiring sheet portion is fixed to the raised portion.

### CROSS-REFERENCE TO RELATED APPLICATIONS

The present patent application claims the priority of Japanese patent application No. 2025/063728 filed on Apr. 8, 2025, and the entire contents of Japanese patent application No. 2025/063728 hereby incorporated by reference.

### TECHNICAL FIELD

The present invention relates to a switch device.

### BACKGROUND ART

Patent Literature 1 discloses a switch device that is mounted on a vehicle and detects touch operation using a capacitive method. The switch device described in Patent Literature 1 includes a sensor sheet including an electrically insulating base material and a detection conductive portion provided on the base material. The detection conductive portion includes an electrode portion capacitively coupled to a user’s finger, and a wiring portion extending from the electrode portion. The sensor sheet is fixed to the vehicle center panel with a double-sided tape.

### Citation List

### Patent Literature

Patent Literature 1: JP 2022/41297A

### SUMMARY OF INVENTION

In the switch device described in Patent Literature 1, however, the wiring portion of the sensor sheet tends to capacitively couple to nearby conductors through the double-sided tape or the center panel to which it is fixed with the double-sided tape, and parasitic capacitance is likely to occur. Therefore, the ratio of parasitic capacitance to the capacitance between the electrode portion and the user’s finger increases, which may reduce the accuracy of detecting operations performed by the user.

It is an object of the invention to provide a switch device capable of accurately detecting operations performed by a user.

An aspect of the invention provides a switch device, comprising:

a panel comprising an operation area where an operation is performed by a user;

a housing to which the panel is fixed; and

a sensor sheet that comprises an electrically insulating base material and a detection conductive portion and is fixed to the housing, the detection conductive portion being provided on the base material and detecting proximity or contact of a finger of the user to or with the operation area,

wherein the detection conductive portion comprises an electrode portion capacitively coupled to the finger of the user during operation on the operation area, and a wiring portion extending from the electrode portion,

wherein the sensor sheet comprises an electrode sheet portion on which the electrode portion is formed, and a wiring sheet portion on which the wiring portion is formed and which is bent from the electrode sheet portion,

wherein the housing comprises a raised portion protruding toward a blank portion of the wiring sheet portion where the wiring portion does not exist, and

wherein the wiring sheet portion is fixed to the raised portion.

### Advantageous Effects of Invention

According to an embodiment of the invention, it is possible to provide a switch device capable of accurately detecting operations performed by a user.

### BRIEF DESCRIPTION OF DRAWINGS

FIG. 1 is a front view showing a switch device in an embodiment.

FIG. 2 is a cross-sectional view taken along line II-II in FIG. 1 as viewed in the arrow direction.

FIG. 3 is a front view showing the switch device in the embodiment, with a panel and a first housing omitted.

FIG. 4 is an enlarged view of a portion of FIG. 3, as partially shown in cross-section.

FIG. 5 is a bottom view showing the switch device in the embodiment, with the panel and the first housing omitted.

FIG. 6 is a front view showing four light guides and a sensor sheet in the embodiment.

FIG. 7 is a cross-sectional view showing the switch device in the embodiment when a pressing operation is being performed in an operation area.

### DESCRIPTION OF EMBODIMENTS

### Embodiment

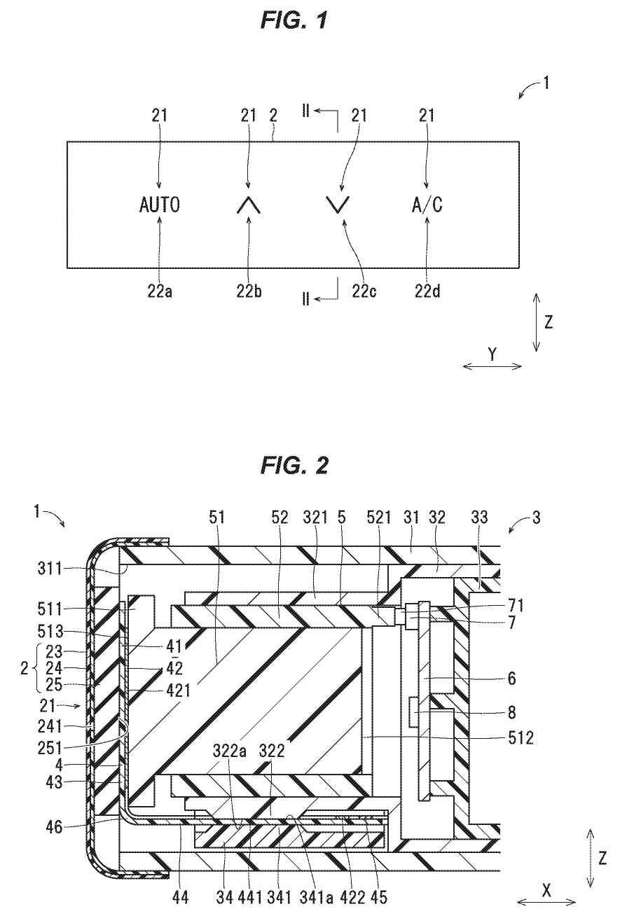

An embodiment of the invention will be described with reference to FIGS. 1-7. The embodiment below is described as a preferred example for implementing the invention. Although some part of the embodiment specifically illustrates various technically preferable matters, the technical scope of the invention is not limited to such specific aspects.

FIG. 1 is a front view showing a switch device 1 in the present embodiment. The switch device 1 in the present embodiment is mounted on, e.g., a vehicle such as an automobile and is used to operate a predetermined in-vehicle device. In the present embodiment, the switch device 1 is attached to an automobile instrument panel and is used to operate an air conditioner. However, the intended use of the switch device 1 is not limited thereto, and the switch device 1 may be used to operate an in-vehicle device other than the air conditioner, such as audio equipment. In addition, the switch device 1 is not limited to a device to be installed in a vehicle.

As shown in FIG. 1, in the present embodiment, the switch device 1 has a panel 2 provided at a position allowing an occupant of a vehicle as a user to see it. The panel 2 has operation areas 21 on which operations are performed by a finger of the user. Marks 22a to 22d representing functions to be executed by the operation are lit in the operation areas 21. In the present embodiment, as an example, the switch device 1 has four operation areas 21 to respectively instruct the air conditioner to perform following functions: (1) turn on/off the automatic control function, (2) increase temperature, (3) decrease temperature, and (4) turn on/off the compressor. Then, in the four operation areas 21, the following marks light up: the mark 22a indicating turn on/off the auto control function, the mark 22b indicating instruction to increase temperature, the mark 22c indicating instruction to decrease temperature, and the mark 22d indicating turn on/off the compressor. In this regard, the number of operation areas 21 is not particularly limited.

In the switch device 1 of the present embodiment, the marks 22a to 22d in the operation areas 21 are normally unlit and not visible. On the other hand, when proximity of the user’s finger is detected within a predetermined range from the panel 2 by a sensor sheet 4 (described later), all the marks 22a to 22d light up. Then, when a displacement detection unit 7 (described later) detects that an operation area 21 has been pressed by the user’s finger, the function assigned to the pressed operation area 21 is executed.

Next, the general overall configuration of the switch device 1 will be described.

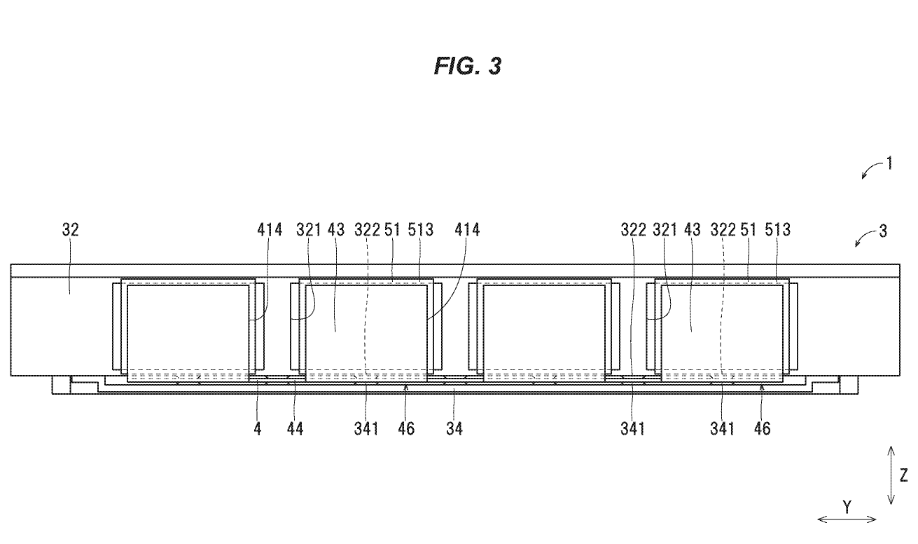

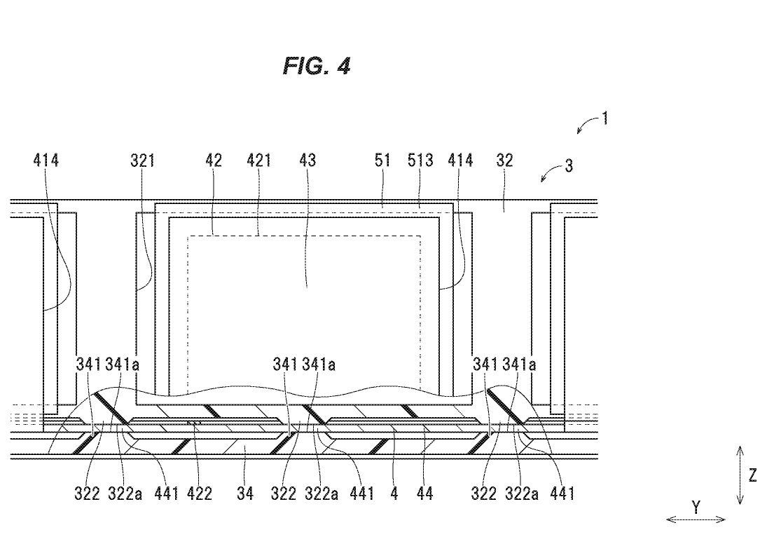

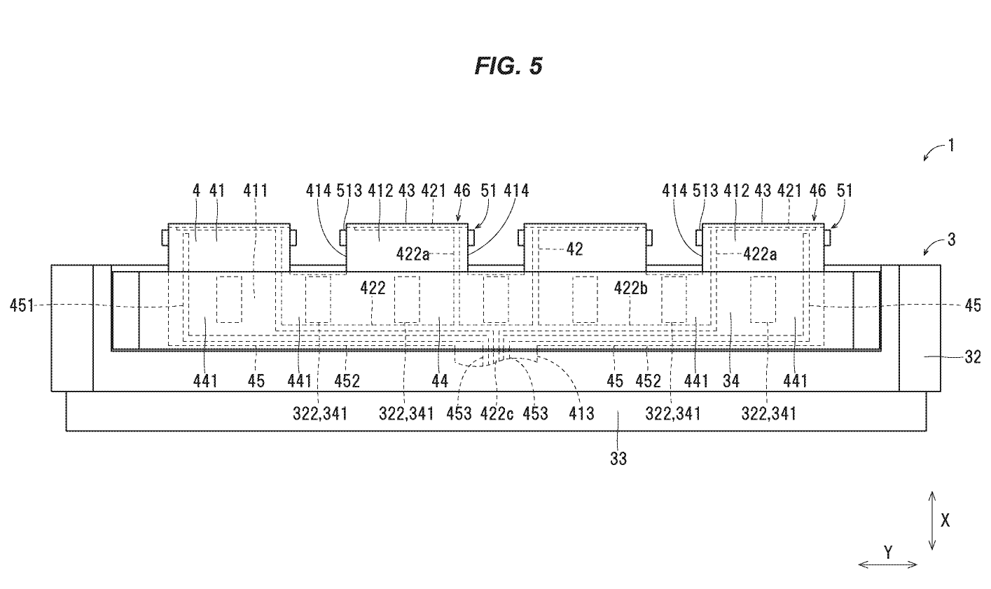

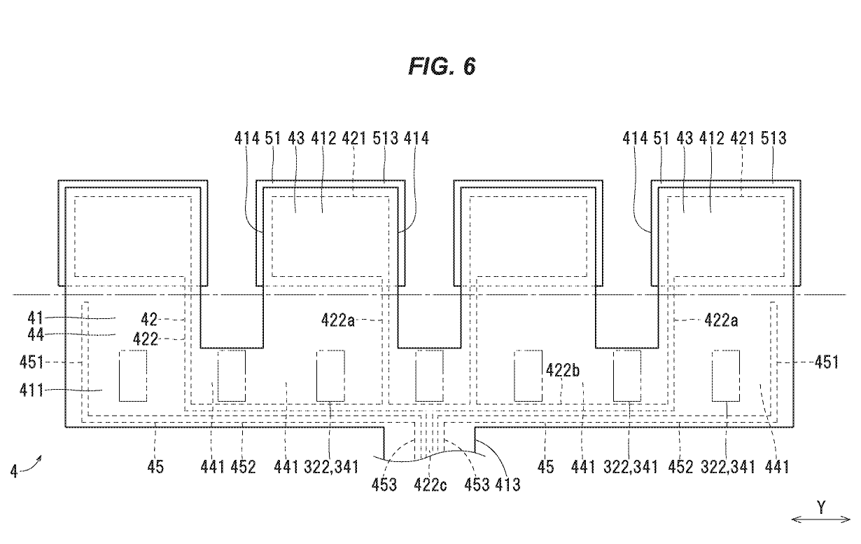

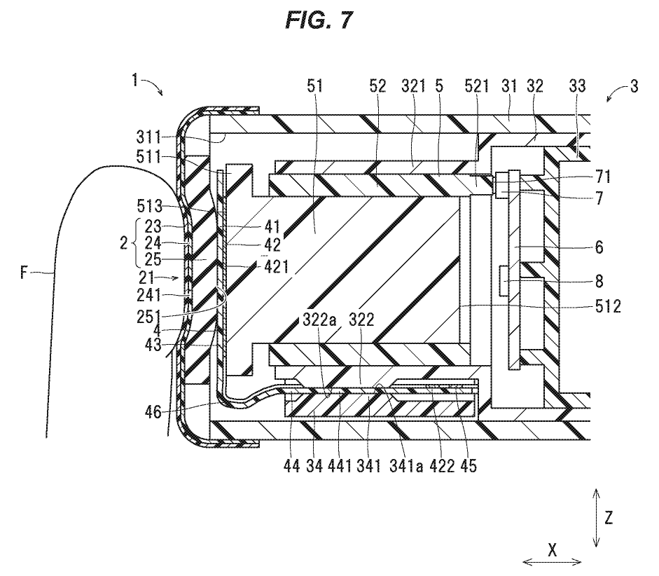

FIG. 2 is a cross-sectional view taken along line II-II in FIG. 1 as viewed in the arrow direction. FIG. 3 is a front view showing the switch device 1, with a panel and a first housing omitted. FIG. 4 is an enlarged view of a portion of FIG. 3, as partially shown in cross-section. FIG. 5 is a bottom view showing the switch device 1, with the panel and the first housing omitted. FIG. 6 is a front view showing four light guides 51 and the sensor sheet 4. The sensor sheet 4 in FIG. 6 is shown in a flattened, unfolded state. FIG. 7 is a cross-sectional view showing the switch device 1 when a pressing operation is being performed in the operation area 21. FIG. 7 shows a cross-section of the switch device 1 when cut at the same location as the cross-section in FIG. 2.

As shown in FIG. 2, the switch device 1 includes the panel 2, a housing 3, the sensor sheet 4, a movable member 5, a substrate 6, the displacement detection unit 7, and a light source 8. As shown in FIG. 1, four operation areas 21 are provided on the panel 2. As shown in FIG. 2, the housing 3 is configured such that the panel 2 is fixed thereto and each component of the switch device 1 is housed therein.

The sensor sheet 4 is fixed to the housing 3 and has flexibility. As shown in FIGS. 2 and 6, the sensor sheet 4 has an electrically insulating base material 41 and a detection conductive portion 42 that is provided on the base material 41 and detects proximity or contact of a finger of the user to or with the operation areas 21. In FIG. 3, the detection conductive portion is omitted. As shown in FIG. 6, the detection conductive portion 42 includes electrode portions 421 capacitively coupled to the user’s finger during operation on the operation areas 21, and a wiring portion 422 extending from the electrode portions 421. In addition, the sensor sheet 4 includes electrode sheet portions 43 on which the electrode portions 421 are formed, and a wiring sheet portion 44 on which the wiring portion 422 is formed and which is bent from the electrode sheet portions 43.

As shown in FIGS. 2 and 7, the movable member 5 displaces in response to a pressing operation on the operation area 21. The displacement detection unit 7 and the light source 8 are mounted on the substrate 6. The displacement detection unit 7 detects the displacement of the movable member 5 caused by the pressing operation. The light source 8 emits light onto the operation area 21, causing the mark 22a – 22d to appear on the operation area 21. In the present embodiment, four electrode sheet portions 43, four movable members 5, four displacement detection units 7, and four light sources 8 are provided so as to respectively correspond to the four operation areas 21.

In the switch device 1 of the present embodiment, a means for fixing the wiring sheet portion 44 of the sensor sheet 4 to the housing 3 is devised. As shown in FIGS. 2, 4 and 5, in the present embodiment, the housing 3 has raised portions 322 and 341 protruding toward a blank portion 441 of the wiring sheet portion 44 where the wiring portion 422 does not exist, and the wiring sheet portion 44 is fixed to the raised portions 322 and 341. This creates an air layer with a relatively low dielectric constant around the wiring portion 422 of the wiring sheet portion 44, which suppresses occurrence of parasitic capacitance due to capacitive coupling between the wiring portion 422 and a nearby conductor. As a result, the ratio of the parasitic capacitance to the coupling capacitance between the electrode portions 421 and the user’s finger is reduced, improving accuracy of detecting operations performed by the user.

Next, the switch device 1 in the present embodiment will be described in detail.

In the present embodiment, the arrangement direction of the panel 2, the electrode sheet portion 43 and the movable member 5 is defined as the front-rear direction X, one side in the front-rear direction X, which is the panel 2 side relative to the electrode sheet portion 43, is defined as the front, and the opposite side is defined as the rear. In addition, the arrangement direction of the four operation areas 21 is defined as the left-right direction Y. Furthermore, the direction perpendicular to both the front-rear direction X and the left-right direction Y is defined as the up-down direction Z.

As shown in FIG. 2, the panel 2 is formed by laminating an exterior panel 23, a mark-forming panel 24, and an elastic panel 25 in this order. The exterior panel 23 constitutes the outermost surface of the panel 2. The exterior panel 23 has operation areas 21 on its front surface that are touched by the user’s finger during a pressing operation. The exterior panel 23 is formed of a material that allows light emitted from the light source 8 to pass through. In this regard, the exterior panel 23 does not need to be transparent to the light emitted from the light source 8 as long as the material does not completely block the light emitted from the light source 8.

The mark-forming panel 24 is provided on the rear surface of the exterior panel 23. The mark-forming panel 24 is formed of a light-blocking material that blocks the light emitted from the light source 8, and holes 241 in the shapes of the marks 22a to 22d are formed on the mark-forming panel 24. The light emitted from the light source 8 passes through the holes 241, allowing the user to see light in the shapes of the marks 22a to 22d. As shown in FIG. 7, the exterior panel 23 and the mark-forming panel 24 are formed thin enough to flex when the user presses the operation area 21 with a finger F.

The elastic panel 25 is provided on the rear surface of the mark-forming panel 24. The elastic panel 25 faces all the four movable members 5 from the front. The elastic panel 25 is formed by shaping an elastic material such as rubber into a sheet shape. The elastic panel 25 is formed thicker than the exterior panel 23 and the mark-forming panel 24, and is thus easily elastically deformed. When the operation area 21 is not being operated by the user, the elastic panel 25 receives a pressing force from the displacement detection unit 7 through the sensor sheet 4 and the movable member 5 and is elastically deformed. In addition, as shown in FIG. 7, the elastic panel 25 is also elastically deformed when the user presses the operation area 21.

The housing 3 has a first housing 31, a second housing 32, a third housing 33, and a fourth housing 34 that are fixed to one another. The first housing 31, together with the panel 2, forms the main exterior appearance of the switch device 1, and the second housing 32, the third housing 33 and the fourth housing 34 are fixed inside the first housing 31. The first housing 31 has four openings 311 in which front end portions 511 of the light guides 51 (described later) of the four movable members 5 are respectively arranged. The front portion of the first housing 31 including the four openings 311 is covered with the panel 2.

As shown in FIGS. 2 and 3, the second housing 32 has four cylindrical portions 321 respectively housing the four movable members 5. The cylindrical portions 321 are formed side by side in the left-right direction Y, and are open on both sides in the front-rear direction X.

As shown in FIG. 2, the third housing 33 is fixed to the second housing 32 so as to close a rear opening of the second housing 32. Then, the substrate 6 is fixed to the third housing 33.

The fourth housing 34 is fixed to the second housing 32 and also fixes the wiring sheet portion 44 of the sensor sheet 4 by sandwiching the wiring sheet portion 44 between itself and the second housing 32. The details of the means for fixing the wiring sheet portion 44 will be described later.

The sensor sheet 4 is of the capacitance type and constitutes a self-capacitance touch sensor. In the present embodiment, the sensor sheet 4 detects proximity of a user’s finger to the operation areas 21 of the panel 2. The sensor sheet 4 is flexible.

As shown in FIG. 6, the sensor sheet 4 includes a base material 41, the detection conductive portion 42 provided on the base material 41, and two ground portions 45.

The base material 41 is composed of a PET (polyethylene terephthalate) sheet, etc. which has electrical insulating properties, flexibility, and light-transmitting properties. The base material 41 has a base portion 411 that is long in the left-right direction Y, four protruding pieces 412 that protrude from the base portion 411 on the same side, and a lead-out portion 413 that protrudes from the base portion 411 on the opposite side to the four protruding pieces 412. The four protruding pieces 412 are arranged at intervals in the left-right direction Y. Slits 414 are formed between adjacent protruding pieces 412. The slits 414 penetrate the base material 41 in the thickness direction, and are open on the side where the protruding pieces 412 protrude from the base portion 411 (on the upper side in FIG. 6).

The detection conductive portion 42 has light-transmitting properties and is formed on a surface of the base material 41. An example in which the detection conductive portion 42 is formed on the surface of the base material 41 on the movable member 5 side is shown in the present embodiment, but the detection conductive portion 42 may be provided on the surface of the base material 41 on the opposite side to the movable member 5. The detection conductive portion 42 is formed by, e.g., vapor deposition or printing, etc. For example, the detection conductive portion 42 is composed of an ITO film or transparent ink, etc. In areas where light does not need to pass through, the detection conductive portion 42 may be formed of a material that does not have light-transmitting properties. The detection conductive portion 42 includes the four electrode portions 421 respectively formed on the four protruding pieces 412, and the wiring portion 422 that is electrically connected to the electrode portions 421 and is formed on the protruding pieces 412, the base portion 411, and the lead-out portion 413.

The electrode portion 421 is a portion capacitively coupled to a finger proximity to the operation area 21 and is designed to have a large surface area that faces the finger. The four electrode portions 421 are arranged side by side at intervals in the left-right direction Y.

The wiring portion 422 is thinner than the electrode portions 421, is formed in a linear shape, and is electrically connected to the electrode portions 421. In the present embodiment, the wiring portion 422 electrically connects the four electrode portions 421 to each other. That is, in the present embodiment, the sensor sheet 4 detects proximity of the user’s finger to any one of the four electrode portions 421, but does not identify proximity to which electrode portion 421.

The wiring portion 422 and the ground portions 45 are formed at portions near the rim of the sensor sheet 4 so that a blank portion 441, in which the wiring portion 422 and the ground portions 45 do not exist, is formed wide on the wiring sheet portion 44 (described later) of the sensor sheet 4. In the present embodiment, the wiring portion 422 has four first portions 422a extending respectively from the four electrode portions 421 in a direction orthogonal to the left-right direction, a second portion 422b extending in the left-right direction Y and electrically connecting the four first portions 422a to each other, and a third portion 422c extending from the second portion 422b on the lead-out portion 413 side.

Each first portion 422a is formed at an end portion of the protruding piece 412 in the left-right direction Y. The end portion of the protruding piece 412 in the left-right direction Y can be a region other than the center when the protruding piece 412 is divided into three equal parts in the left-right direction Y as an example, and the second portion 422b is formed at an end portion of the base portion 411 in a direction orthogonal to the left-right direction Y. The end portion of the base portion 411 in a direction orthogonal to the left-right direction Y can be a region other than the center when the base portion 411 is divided into three equal parts in a direction orthogonal to the left-right direction Y, as an example. In the present embodiment, the second portion 422b is formed at an end portion of the base portion 411 on the lead-out portion 413 side in the direction orthogonal to the left-right direction Y. The third portion 422c is electrically connected to the substrate 6.

The ground portion 45 is connected to ground potential when the switch device 1 is in use (e.g., in a state in which the switch device 1 is mounted on a vehicle when the switch device 1 is for in-vehicle use). Each ground portion 45 includes a first portion 451 formed parallel to the first portion 422a of the wiring portion 422, a second portion 452 formed parallel to the second portion 422b of the wiring portion 422, and a third portion 453 formed parallel to the third portion 422c of the wiring portion 422.

The first portions 451 of the two ground portions 45 are formed respectively at both end portions of the base portion 411 in the left-right direction Y. The first portion 451 is formed at an end portion of the protruding piece 412 in the left-right direction Y on the opposite side to the first portion 422a. The first portion 451 is formed from the second portion 452 up to a position just before a bending position which is indicated by a dash-dot line in FIG. 6. In this regard, the first portion 451 may be omitted. The second portion 452 is formed at a position on the lead-out portion 413 side relative to the second portion 422b. The third portion 453 is formed from the second portion 452 on the lead-out portion 413 side.

As shown in FIG. 2, the sensor sheet 4 is attached in a state of being bent in the thickness direction, and has the four electrode sheet portions 43 and the wiring sheet portion 44 with a bent portion 46 therebetween. The bent portion 46 is formed at a position between the four electrode portions 421 and the base portion 411, specifically, at a position between the electrode portions 421 and the ground portions 45 in the present embodiment.

The four electrode sheet portions 43 are formed so as to intersect the front-rear direction X and are arranged to respectively face the front surfaces of the four movable members 5 (front surfaces 513 of the light guides 51 in the present embodiment). The electrode sheet portion 43 is a portion with the electrode portion 421 formed thereon, and is composed of a portion of the protruding piece 412 on the opposite side to the base portion 411. Although the example in which the electrode sheet portion 43 is parallel to the up-down direction Z and the left-right direction Y is shown in FIG. 2, etc., it is not limited thereto. The electrode sheet portion 43 may be, e.g., formed in a direction inclined relative to the up-down direction Z.

The electrode sheet portion 43 is sandwiched and held between the movable member 5 and the elastic panel 25, and adheres tightly to the front surface 513 of the light guide 51 of the movable member 5 and to a rear surface 251 of the elastic panel 25. The electrode sheet portion 43 is flexible and thus easily adheres tightly to the front surface 513 of the light guide 51. In addition, the electrode sheet portion 43 may be temporarily attached to the front surface 513 of the light guide 51 with a double-sided tape, etc. at, e.g., a position not blocking the light path from the light source 8 to the operation area 21. The light emitted from the light source 8 passes through the light guide 51, the electrode portion 421 and the base material 41 and reaches the panel 2.

As shown in FIGS. 3 to 6, the slits 414 are formed between the electrode sheet portions 43 adjacent to each other. Therefore, when one operation area 21 is pressed and the electrode sheet portion 43 corresponding to that operation area 21 moves rearward, the other electrode sheet portions 43 are prevented from being pulled by this movement.

However, when the slits 414 are formed, it is difficult to ensure that the electrode portions 421 have an enough area, and also, the wiring portion 422 connected to the electrode portion 421 of each electrode sheet portion 43 needs to be formed and this increases the area ratio of the wiring portion 422 in the detection electrode layer. Therefore, the ratio of parasitic capacitance to the coupling capacitance between the electrode portion 421 and a human finger tends to become large. Furthermore, in case of detecting proximity of a finger to the operation area 21 rather than its contact as in the present embodiment, it is necessary to detect a finger located relatively far away, hence, it is particularly necessary to reduce the parasitic capacitance. Therefore, in the present embodiment, the parasitic capacitance is reduced by devising the means for fixing the wiring sheet portion 44 as described later.

As shown in FIG. 5, the wiring sheet portion 44 is formed along the front-rear direction X and the left-right direction Y. The wiring sheet portion 44 is a portion with the wiring portion 422 and the two ground portions 45 formed thereon and is composed of portions of the protruding pieces 412 other than the electrode sheet portions 43, the base portion 411, and the lead-out portion 413. The wiring sheet portion 44 is devised so that the blank portion 441, in which the wiring portion 422 and the ground portions 45 do not exist, is formed to be wide as described above. The wiring sheet portion 44 is fixed to the second housing 32 and the fourth housing 34 at the blank portion 441. Then, the region of the wiring sheet portion 44 where the wiring portion 422 and the ground portions 45 exist faces the air layer.

The details of the means for fixing the wiring sheet portion 44 to the second housing 32 and the fourth housing 34 will be described. As shown in FIGS. 2, 4 and 5, the second housing 32 has plural raised portions 322 protruding toward the blank portion 441. In the present embodiment, the raised portions 322 are formed so as to protrude toward the blank portion 441 of the base portion 411. In addition, the plural raised portions 322 are formed in regions in the left-right direction Y where the protruding pieces 412 exist and where the slits 414 exist. Facing surfaces 322a of the raised portions 322 that face the blank portion 441 are formed in a flat shape parallel to the blank portion 441.

The fourth housing 34 has plural raised portions 341 formed at positions respectively facing the plural raised portions 322 of the second housing 32. In the present embodiment, the formation regions of the raised portions 322 are respectively the same as the formation regions of the raised portions 341 as viewed in the up-down direction Z, and the raised portion 322 and the corresponding raised portion 341 are represented by a common dashed line in FIG. 5. However, these formation regions do not need to be the same. Facing surfaces 341a of the raised portions 341 that face the blank portion 441 is formed in a flat shape parallel to the blank portion 441.

The wiring sheet portion 44 is sandwiched and held by the plural raised portions 322 and the plural raised portions 341 only at the blank portion 441. The plural raised portions 322 and the plural raised portions 341 sandwich the base portion 411 at plural locations in the left-right direction Y, thereby suppressing local stress concentration on the sensor sheet 4. In addition, in the present embodiment, the plural raised portions 322 and the plural raised portions 341 do not sandwich the protruding pieces 412, which allows the protruding pieces 412 to easily flex and deform during a pressing operation. In this regard, however, the plural raised portions 322 and the plural raised portions 341 may partially sandwich the protruding pieces 412. The wiring sheet portion 44 is fixed to the second housing 32 and the fourth housing 34 as described above.

As shown in FIGS. 5 and 6, the ground portions 45 are formed on the wiring sheet portion 44 and are not formed on the electrode sheet portions 43. This suppresses an increase in the coupling capacitance between the electrode portions 421 and the ground portions 45, and as a result, a decrease in operation detection accuracy caused by a relative decrease in coupling capacitance between the user’s finger and the electrode portions 421 is suppressed.

As shown in FIGS. 2 and 7, the movable member 5 is arranged inside the cylindrical portion 321 so as to be translationally movable in the front-rear direction X. In the present embodiment, the movable member 5 has the light guide 51 to guide the light emitted from the light source 8, and an enclosing member 52 that surrounds around the light guide 51.

The light guide 51 is formed of a material transmitting the light emitted from the light source 8. The light guide 51 is formed of, e.g., a light-transmitting resin, or glass, etc. The light guide 51 is designed so that light entering the interior from a rear surface 512 is guided to the front surface 513 and extracted from the front surface. The front surface 513 and the rear surface 512 of the light guide 51 are formed in a flat shape in the present embodiment, but are not limited thereto and may be curved surfaces. The example in which the normal directions to the front surface 513 and the rear surface 512 coincide with the front-rear direction X is described in the present embodiment, but at least one of these normal directions may be a direction inclined relative to the front-rear direction X.

The light guide 51 has a substantially columnar shape formed along the front-rear direction X, and its front end portion 511 has a shape that widens outward. The front end portion 511 is arranged at a position on the front side relative to the enclosing member 52 and the cylindrical portion 321.

The enclosing member 52 has a cylindrical shape and surrounds the light guide 51 all around. The enclosing member 52 spatially separates the light guide 51 from the sliding portion between the cylindrical portion 321 and the enclosing member 52, thereby suppressing the reach of lubricant on the sliding portion to the light guide 51.

The enclosing member 52 has a push portion 521 protruding rearward. The push portion 521 is in contact with a push button 71 of the displacement detection unit 7 and pushes in the push button 71 when a pressing operation is performed on the operation area 21. Meanwhile, when the switch device 1 is not being operated by the user, the push portion 521 is elastically pressed toward the panel 2 by an elastic restoring force of the displacement detection unit 7, and the movable member 5 is thereby pressed toward the panel 2.

In this regard, the enclosing member 52 can be omitted when, e.g., there is little concern that the lubricant on the sliding portion will reach the light guide 51.

The substrate 6 is composed of, e.g., a rigid printed circuit board, and is arranged in an orientation where its normal direction coincides with the front-rear direction X. In the present embodiment, the substrate 6 is formed to be long in the left-right direction Y and faces all the plural light guides 51 from the rear. On the front surface of the substrate 6, four displacement detection units 7 and four light sources 8 are mounted corresponding to the four operation areas 21.

The displacement detection unit 7 is a mechanical-type switch in which the on/off state of contacts is switched in response to a pressing operation performed on the operation area 21 by the user. The displacement detection unit 7 has an elastic member resisting a pressing operation, and is composed of, e.g., a tact switch, etc. The push button 71 of the displacement detection unit 7 is in contact with the push portion 521 of the enclosing member 52. As shown in FIG. 7, when a pressing operation is performed on the operation area 21, the panel 2 and the sensor sheet 4 flex, the push button 71 is pressed by the push portion 52 as the movable member 5 translationally moves rearward, and the displacement detection unit 7 detects the pressing operation.

In the present embodiment, the displacement detection unit 7 also serves as an elastic unit that elastically presses the movable member 5 toward the panel 2. When an operation is not being performed by the user, the displacement detection unit 7 is arranged in a state in which pressure is applied to its internal elastic member, i.e., in a preloaded state. Thus, the displacement detection unit 7 presses the movable member 5 toward the panel 2 by an elastic restoring force of the internal elastic member.

The light source 8 illuminates the panel 2 with light through the light guide 51 and the sensor sheet 4, causing the mark 22a – 22d to be lit on the panel 2. The light source 8 emits light with a wide divergence toward the front and is composed of, e.g., an LED (Light-Emitting Diode).

Although not shown, the switch device 1 further includes a control unit. The control unit includes, e.g., a control area including a processor and a RAM (Random Access Memory) serving as an arithmetic area when the processor is operating, and a storage area having a ROM (Read Only Memory), a hard disk, etc., and storing programs executed by the processor, etc. The method of implementing the control unit is not limited to that using software as long as the control unit is configured to be able to execute its functions. For example, at least some of the functions of the control unit may be executed using hardware such as logic circuit.

The control unit receives detection results from the sensor sheet 4 and the four displacement detection units 7. When proximity of a finger to any of the operation areas 21 is detected using the sensor sheet 4, all the four light sources 8 are turned on so that the four marks 22a to 22d are visible. Then, when a pressing operation on an operation area 21 is detected by the displacement detection unit 7, an instruction signal is transmitted to the air conditioner so that the corresponding function is executed. Then, once the proximity of the finger to the operation area 21 ends, the control unit turns off the light sources 8.

(Functions and Effects of the embodiment)

In the switch device 1 of the present embodiment, the housing 3 has the raised portions 322 and 341 protruding toward the blank portion 441 of the wiring sheet portion 44 where the wiring portion 422 does not exist, and the wiring sheet portion 44 is fixed to the raised portions 322 and 341. This suppresses placement of a material with a relatively high dielectric constant (e.g., a portion of the housing 3), etc. near the wiring portion 422 of the wiring sheet portion 44, resulting in that occurrence of parasitic capacitance due to capacitive coupling between the wiring portion 422 and a nearby conductor is suppressed. As a result, the ratio of the parasitic capacitance to the coupling capacitance between the electrode portion 421 and the user’s finger is reduced, improving accuracy of detecting operations performed by the user.

In addition, when the side of the wiring sheet portion 44 where the wiring portion 422 is formed on the base material 41 is defined as a wiring side, the raised portions 322, 341 are provided at least on the wiring side of the blank portion 441. In the case of the present embodiment, the wiring portion 422 is formed on the wiring sheet portion 44 on the movable member 5 side of the base material 41, and the raised portions 322 are formed on the second housing 32 that is located on the movable member 5 side relative to the blank portion 441. Particularly when resin, etc. is arranged in contact with the side of the wiring sheet portion 44 where the wiring portion 422 is located, the wiring portion 422 and a nearby conductor are likely to be capacitively coupled through the resin, etc., and the parasitic capacitance is likely to increase. Therefore, by providing the raised portions 322 at least on the wiring side of the blank portion 441 as in the present embodiment, occurrence of the parasitic capacitance can be further suppressed.

In addition, the wiring sheet portion 44 is sandwiched and held between the raised portions 322 and 341 of the housing 3 formed respectively on both sides of the blank portion 441. Therefore, occurrence of the parasitic capacitance can be further suppressed.

In addition, the sensor sheet 4 includes the plural electrode sheet portions 43 each provided between the panel 2 and one of the plural movable members 5, and the slits 414 are formed between adjacent electrode sheet portions 43. In addition, the electrode portions 421 of the plural electrode sheet portions 43 are connected to one another by the wiring portion 422. In case of having such a configuration, it is difficult to ensure that the electrode portions 421 have an enough area, and also, the wiring portion 422 connected to the electrode portion 421 of each electrode sheet portion 43 needs to be formed, and this increases the proportion of the area of the wiring portion 422 in the detection conductive portion 42, hence, the ratio of parasitic capacitance to the coupling capacitance between the electrode portion 421 and a human finger tends to become large. Therefore, the switch device 1 in the present embodiment, which can suppress occurrence of parasitic capacitance, is preferably used.

In addition, the sensor sheet 4 further has the ground portions 45. Then, the ground portions 45 are formed on the wiring sheet portion 44 and are not formed on the electrode sheet portions 43. This suppresses an increase in the coupling capacitance between the electrode portions 421 and the ground portions 45, and as a result, a decrease in operation detection accuracy caused by a relative decrease in coupling capacitance between the user’s finger and the electrode portion 421 is suppressed.

As described above, according to the present embodiment, it is possible to provide a switch device capable of accurately detecting operations performed by a user.

### Modifications

Next, possible modifications of the switch device 1 in the embodiment will be described.

The example in which the blank portion 441 of the wiring sheet portion 44 is sandwiched and held between the raised portions 322 of the second housing 32 and the raised portions 341 of the fourth housing 34 has been shown in the embodiment, but the configuration may be such that, e.g., one of the second housing 32 and the fourth housing 34 does not have raised portions.

In addition, the example in which the blank portion 441 of the wiring sheet portion 44 is sandwiched and fixed has been shown in the embodiment, but the fixing means is not limited to sandwiching. For example, the blank portion 441 may be fixed to the housing 3 by adhesion, etc. In this case, e.g., the blank portion 441 of the wiring sheet portion 44 may be adhered to the raised portions 322 of the second housing 32, and the fourth housing 34 may be omitted.

In addition, the movable member 5 has the light guide 51 in the embodiment, but it is not limited thereto.

In addition, the switch device 1 in the embodiment is configured such that proximity of a finger to the operation area 21 is detected using the sensor sheet 4 and a pressing operation on the operation area 21 is detected using the displacement detection unit 7, but the configuration is not limited thereto. For example, the displacement detection unit 7 may be omitted by configuring to turn on the light sources 8 upon detection of proximity of a finger to the operation area 21 by the sensor sheet 4 and transmit a predetermined instruction to the air conditioner, etc., upon detection of contact with the operation area 21 (i.e., a touch operation) by the sensor sheet 4. In this case, the circuit of the sensor sheet 4 is configured so as to be able to detect which of the four operation areas 21 is touched. In addition, in this case, the light guide 51 does not need to move relative to the housing 3, allowing, e.g., the enclosing member 52 to be omitted.

In addition, the displacement detection unit 7 is composed of a mechanical-type switch in the embodiment, but is not limited thereto as long as displacement of the movable member 5 due to a pressing operation on the operation area 21 can be detected. For example, the displacement detection unit 7 may be a sensor, etc. that detects displacement of the movable member 5 using an optical method such as ToF (Time of Flight).

Although the embodiment of the invention has been described, the invention according to claims is not to be limited to the above-described embodiment. Further, please note that not all combinations of the features described in the embodiment are necessary to solve the problem of the invention. In addition, the invention can be appropriately modified and implemented without departing from the gist thereof.

### REFERENCE SIGNS LIST

1 SWITCH DEVICE
2 PANEL
21 OPERATION AREA
3 HOUSING
322 RAISED PORTION
341 RAISED PORTION
4 SENSOR SHEET
5 MOVABLE MEMBER
7 DISPLACEMENT DETECTION UNIT
41 BASE MATERIAL
414 SLIT
42 DETECTION CONDUCTIVE PORTION
421 ELECTRODE PORTION
422 WIRING PORTION
43 ELECTRODE SHEET PORTION
44 WIRING SHEET PORTION
441 BLANK PORTION
45 GROUND PORTION
F FINGER

1. A switch device, comprising:
a panel comprising an operation area where an operation is performed by a user;
a housing to which the panel is fixed; and
a sensor sheet that comprises an electrically insulating base material and a detection conductive portion and is fixed to the housing, the detection conductive portion being provided on the base material and detecting proximity or contact of a finger of the user to or with the operation area,
wherein the detection conductive portion comprises an electrode portion capacitively coupled to the finger of the user during operation on the operation area, and a wiring portion extending from the electrode portion,
wherein the sensor sheet comprises an electrode sheet portion on which the electrode portion is formed, and a wiring sheet portion on which the wiring portion is formed and which is bent from the electrode sheet portion,
wherein the housing comprises a raised portion protruding toward a blank portion of the wiring sheet portion where the wiring portion does not exist, and
wherein the wiring sheet portion is fixed to the raised portion.

2. The switch device according to claim 1, wherein when a side of the wiring sheet portion where the wiring portion is formed on the base material is defined as a wiring side, the raised portion is provided on at least the wiring side of the blank portion.

3. The switch device according to claim 2, wherein the wiring sheet portion is sandwiched and held between the raised portions of the housing that are respectively formed on both sides of the blank portion.

4. The switch device according to claim 1, wherein the housing comprises a plurality of the operation areas, the switch device further comprises a plurality of movable members displacing in response to pressing operations respectively on the plurality of operation areas, and a displacement detection unit to detect displacement of each of the plurality of movable members, wherein the sensor sheet comprises a plurality of the electrode sheet portions each provided between the panel and one of the plurality of movable members, and a slit formed between the electrode sheet portions adjacent to each other, and wherein the electrode portions of the plurality of electrode sheet portions are connected to one another by the wiring portion.

5. The switch device according to claim 1, wherein the sensor sheet further comprises a ground portion, and wherein the ground portion is formed on the wiring sheet portion and is not formed on the electrode sheet portion.

6. The switch device according to claim 1, wherein the raised portion is configured to expand an air layer existing around the wiring portion in a thickness direction of the sensor sheet.

7. The switch device according to claim 1, wherein the wiring portion is formed at a rim of the sensor sheet such that the blank portion is formed wide.

8. The switch device according to claim 1, wherein the sensor sheet is configured to constitute a self-capacitance touch sensor.
